(19) United States
(12) Patent Application Publication
(10) Pub. No.: US 2005/0121734 A1
(43) Pub. Date: Jun. 9, 2005

(54) Combination catheter devices, methods, and systems

(75) Inventors: F. Levent Degertekin, Decatur, GA (US); Stephane Guy Carlier, New York, NY (US)

Correspondence Address: TROUTMAN SANDERS LLP, BANK OF AMERICA PLAZA, SUITE 5200, 600 PEACHTREE STREET , NE, ATLANTA, GA, 30308-2216, US

(73) Assignees: Georgia Tech Research Corporation, Atlanta, GA (US); Cardiovascular Research Foundation, New York, NY (US)

(21) Appl. No.: 10/983,886

(22) Filed: Nov. 8, 2004

Related U.S. Application Data
(60) Provisional application No. 60/518,549, filed on Nov. 7, 2003.

(51) Int. Cl. H01L 21/00; H01L 27/14; H01L 29/82

(52) U.S. Cl. 257/414; 438/48

(57) ABSTRACT

A combination catheter method, system, and device are provided having a capacitive-micromachined ultrasound transducer (“cMUT”) and a sensor fabricated on the same substrate. A substrate is provided, and various layers of materials are deposited onto the substrate and patterned to form a cMUT and one or more sensors. Other embodiments are also claimed and described.

### CROSS REFERENCE TO RELATED APPLICATION AND PRIORTY CLAIM

This Application is based on and claims the priority date of U.S. Provisional Application Ser. No. 60/518,549 filed on 6 Nov. 2003, which is incorporated by reference in its entirety as if fully set forth herein.

### TECHNICAL FIELD

The various embodiments of the invention relate generally to the field of chip fabrication, and more particularly, to fabricating a capacitive micromachined ultrasonic transducer (“cMUT”) imaging array and one or more sensors on the same substrate.

### BACKGROUND

Micro-electro-mechanical system (MEMS) manufacturing processes have launched many innovations in many different technical fields in recent years. The medical devices field is one technical field that has greatly benefited from MEMS technology. MEMS technology allows medical devices to be manufactured in very small packages. Intravascular imaging and interventions is a particular area where miniaturized devices are critical. One example of such a MEMS-type medical device is an intravascular ultrasound imaging device (IVUS) placed on a catheter. An IVUS provides real-time tomographic images of blood vessel cross sections, elucidating the true morphology of the lumen and transmural components of atherosclerotic arteries. Ultrasound imaging from within the artery may be achieved by placing a transducer around the tip of a catheter. These catheters are typically highly flexible and can be advanced on a guide-wire in the epicardial coronary arteries. IVUS catheters used in coronary arteries are quite small, usually around 1 mm in diameter. With this small size and real-time imaging capabilities, IVUS also provides a means for monitoring and guiding interventions.

Device manufacturers have greatly reduced the physical size of certain other medical devices, allowing medical professionals to obtain critical information from within a patient's body while utilizing minimally invasive medical procedures.

One use of such equipment involves inserting a pressure sensor placed on a thin wire into a blood vessel to obtain data regarding pressure fluctuations in the vessel during normal cardiovascular processes. MEMS technology has been used to manufacture such miniaturized pressure sensors. Similarly, piezoelectric devices for blood flow measurements based on Doppler processing have been miniaturized and used to estimate the average and maximum blood flow rate in arteries. These devices may be used to measure intracoronary blood flow and pressure variations along the arteries under various physiological conditions to assess the hemodynamics in the blood vessels. Unfortunately, current systems require that the pressure measurements and the ultrasound images be captured in distinct time periods. Thus, the data must be captured separately and then correlated based on time tags triggered to the cardiovascular cycles. Such methods, while helpful, are replete with problems. For example, the procedure is not reliable if the patient's cardiovascular cycle changes between the two readings. Since patients may encounter various stresses, or be uncomfortable, during the measurements, it is not uncommon for the data to be flawed.

Therefore, there is a need in the art for IVUS catheters that are capable of capturing image data and sensor data simultaneously.

Additionally, there is a need in the art for a fabrication process capable of producing a device capable of capturing image data and sensor data simultaneously.

### SUMMARY

In accordance with the various embodiments of the present invention, the above and other problems are solved by combination catheter devices, methods, and systems. The various exemplary embodiments of the present invention allow a cMUT imaging array and a sensor to be formed on the same substrate and also enable device manufactures to fabricate a cMUT imaging array and various chemical or physical sensors on the same substrate. Additionally, the various exemplary embodiments of the present invention enable device manufacturers to fabricate MEMS devices on a substrate with embedded integrated electronics.

In one aspect of the invention, a combination catheter device may include a substrate having a first surface, and a cMUT and a sensor coupled to the first surface of the substrate.

In accordance with other aspects, the present invention relates to a method for fabricating a combination catheter device having a cMUT and a sensor formed on the same substrate. According to one method, a substrate is provided, and an isolation layer may be deposited and patterned on the substrate. Next, a first conductive layer may be deposited and patterned on the isolation layer and a sacrificial layer may be deposited and patterned on the first conductive layer. Once the sacrificial layer is patterned to a predetermined configuration, a first membrane layer may be deposited and patterned on the sacrificial layer, followed by the deposition and patterning of a second conductive layer on the first membrane layer. A second membrane layer may then be deposited and patterned on the second conductive layer and the sacrificial layer may be etched away forming a cavity between the first and second conductive layers.

These and various other features as well as advantages, which characterize the various exemplary embodiments of present invention, will be apparent from a reading of the following detailed description and a review of the associated drawings.

### BRIEF DESCRIPTION OF THE DRAWINGS

FIG. 1 is an illustration of a top view of a capacitive micromachined ultrasonic transducer (“cMUT”) imaging array and multiple sensors formed on the same substrate in accordance with an exemplary embodiment of the present invention.

FIG. 2 is an illustration of a side view of cMUTs and sensors formed on a silicon substrate in accordance with an exemplary embodiment of the present invention.

FIG. 3 is an illustration of a side view of cMUTs and sensors formed on a transparent substrate in accordance with an exemplary embodiment of the present invention.

FIG. 4 is an illustration of a fabrication process utilized to produce a cMUT and a capacitive pressure sensor on a silicon substrate in accordance with an exemplary embodiment of the present invention.

FIG. 5 is an illustration of a fabrication process utilized to produce a cMUT and a piezoresistive pressure sensor on a silicon substrate in accordance with an exemplary embodiment of the present invention.

FIG. 6 is an illustration of a fabrication process utilized to produce a cMUT and a pressure sensor on a transparent substrate in accordance with an exemplary embodiment of the present invention.

FIG. 7 is a logic flow diagram depicting a method of fabricating a combination catheter device in accordance with an exemplary embodiment of the present invention.

### DETAILED DESCRIPTION

Simultaneous IVUS imaging of the blood vessels and pressure or flow measurements may yield valuable information such as the detection of vulnerable coronary plaque, the assessment of the hemodynamic effect of a stenosis, and the assessment of the endothelial function.

The disruption of coronary plaques with superimposed thrombosis is the primary cause of acute coronary events, such as unstable angina pectoris, acute myocardial infarction, and sudden coronary death. The two major mechanisms underlying plaque disruption are the rupture of a fibrous cap of a lipid-rich plaque, and the denudation and erosion of the endothelial surface. The risk of plaque rupture may depend more on the plaque type than on the plaque size. Most ruptures occur in plaques containing a soft, lipid-rich core covered by an inflamed thin cap of fibrous tissue. Compared with intact caps, the ruptured ones are thinner, contain less collagen (with a reduced tensile strength), fewer smooth muscle cells, and more macrophages. The major determinants of plaque vulnerability to rupture are progressive lipid accumulation and cap weakening, secondary to inflammation with collagen degradation and impaired healing. These intrinsic plaque changes predispose plaques to rupture, but extrinsic forces (e.g. haemodynamic stresses) will determine the actual time of rupture by triggering it.

The propensity of a lesion to rupture is poorly predicted by coronary X-ray angiography, which is not surprising since vulnerability is related to its composition and not its size. IVUS is currently the only imaging modality that provides real-time cross-sectional images of blood vessels at high resolution. However, the characterization of vascular tissue using conventional ultrasound is currently limited. Several investigators are actively developing alternate IVUS imaging techniques for characterizing the mechanical and acoustic properties of vascular tissues in vivo. The results of preliminary clinical evaluation of these techniques have been very encouraging. Processing of the backscattered ultrasound radiofrequency signal, combined with pressure measurements, gives additional information about the mechanical stress and strain in a given plaque. This approach, coined intravascular elastography and palpography, was recently able to detect rupture-prone plaque. Thus, it is desirable to combine an IVUS scanner and a pressure sensor on the same catheter for these emerging techniques such as elastography.

Major epicardial coronary vessels contribute to the coronary vascular resistance, but they act primarily as conductance vessels. Most of the resistance to coronary blood flow arises from the intramural arterioles of less than 200 micrometers in diameter. The resting coronary flow does not decrease until there is approximately a 90% diameter stenosis of the epicardial vessel. On the contrary, the maximal achievable flow begins to decrease when the percent diameter stenosis exceeds approximately 50%. The coronary flow reserve, defined as the ratio of coronary flow at maximum vasodilatation to the flow at rest, has been proposed as a measure of stenosis severity. The fractional flow reserve, in its simplified form, computed as the ratio during full hyperemia of the pressure distal to a stenosis to the pressure proximal to it, evaluates the percentage of the maximal flow one would measure in that artery without the interrogated stenosis. These assumptions are derived from the complex hemodynamic principles regulating the coronary circulation. At rest, flow is independent from the driving pressure over a wide range (60 to 180 mm Hg) of physiologic pressures, a phenomenon classically described as autoregulation of the coronary circulation. During maximal vasodilation, flow becomes linearly related to the driving pressure. The presence of a flow-limiting stenosis in a major epicardial vessel generates a pressure drop across the stenotic lesion that is the result of viscous and turbulent resistances, so that the driving pressure distal to the stenosis decreases non-linearly in response to the flow increase.

Developments of miniaturized pressure and Doppler transducers, mounted on 0.014-inch guide wires, have resolved the initial fluid dynamics problems of flow impediment. The clinical importance of the coronary flow reserve (CFR) distal to a stenosis, derived from Doppler recordings, or of the myocardial fractional flow reserve (FFRmyo), derived from pressure recordings, has been extensively demonstrated. The safety of not performing an angioplasty for intermediate stenoses without a functionally significant severity assessed by flow or pressure measurements has also been demonstrated. There are also morphological criteria based on the minimal lumen area measured by IVUS (>4 mm²) that are used to safely defer an intervention. However, cases where there is no agreement between these different modalities are not uncommon and an integrated catheter allowing simultaneously morphological and physiological measurements is not available. At present one has to use an IVUS catheter, then a Doppler wire and/or a pressure wire. Therefore, combining a Doppler transducer and/or a pressure sensor with the IVUS catheter on the same substrate would be desirable to reduce catheterization time providing both the pressure recordings and the morphology of the blood vessels during a single intervention.

Another field of application of intracoronary Doppler is the evaluation of early stages of coronary atherosclerosis, without the presence of an epicardial stenosis, while there is a functional impairment of coronary vasodilator capacity and endothelial dysfunction. An endothelium derived relaxing factor, identified as nitric oxide modulates vascular tone in response to physiologic and pathologic stimuli. Endothelial damage, leading to a decreased formation or release of nitric oxide from its precursor L arginine, or reduced penetration due to the presence of subendothelial intimal thickening, are possible explanations of the impairment of endothelium mediated vasodilation observed in patients with systemic hypertension, hypercholesterolemia, diabetes mellitus, and atherosclerosis. The presence of a paradoxical vasoconstriction induced by acetylcholine has been shown in coronary arteries of patients at sites of severe stenosis or moderate wall irregularities and in angiographically normal segments. Coronary artery endothelial dysfunction predicts cardiovascular events in patients with coronary atherosclerosis.

Conventionally, endothelial dysfunction is assessed only using coronary angiography and an increasing infusion of ACh intracoronary. Additional flow measurements have been advocated by several experts since there might be a large variability in the degree and geographical distribution of the vasoconstriction along one coronary segment. One of the reasons is the variability in the accumulation of plaque, that IVUS can demonstrate. Systematic IVUS interrogation in this setting has been recommended. The availability of a combined catheter offering the possibility to follow the changes in the coronary blood flow, blood pressure and cross-sectional area would offer the possibility to assess completely the epicardial vessel integrity, as well as computing from the simultaneously acquired pressure and flow data the distal vascular resistance and impedance, related to the microvascular bed. Therefore, Doppler and pressure sensors combined with forward looking IVUS imaging arrays would be desired to increase the efficacy of these coronary interventions.

In addition to flow and pressure sensors, different sensors which would normally be used to measure various normal or drug-induced physiological activity within the blood vessels may be combined with an IVUS imaging array. Such a combined device would reduce the intervention duration by simultaneously providing real-time IVUS images and sensor output.

Referring now the drawings, in which like numerals represent like elements, exemplary embodiments of the present invention are described below.

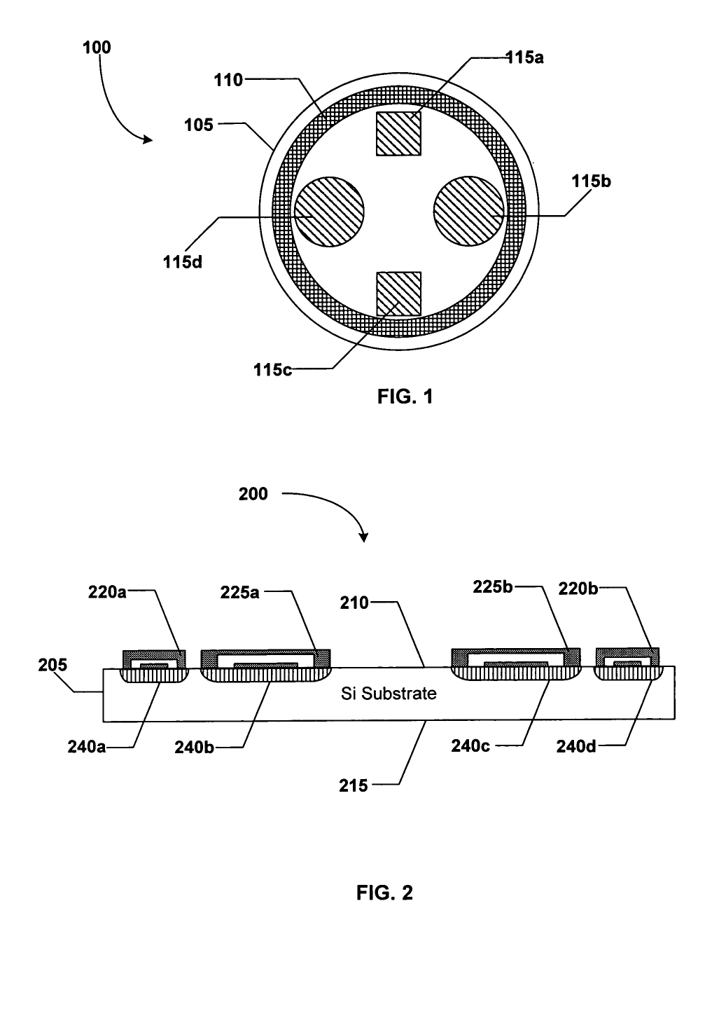

FIG. 1 is an illustration of a top view of a combination catheter device 100 having a capacitive micromachined ultrasonic transducer (“cMUT”) imaging array and multiple sensors formed on the same substrate in accordance with an exemplary embodiment of the present invention. As shown, the device 100 may include a substrate 105, a cMUT imaging array 110, and various sensors 115a-d formed on a surface of the substrate 105. The device 100 is shown in a forward looking arrangement with a ring-annular cMUT imaging array 110 formed on an outer periphery of substrate 105. A ring-annular array may be any type of annular ring array or annular array. The cMUT imaging array 110 may include a plurality of cMUTs arranged in a predetermined configuration. Additionally, the sensors 115a-d may be placed inside the annular cMUT array 110. In other exemplary embodiments, the device 100 may be arranged in different topologies or arrangements. For example, device 100 may be arranged in a side looking arrangement or the substrate can be placed at an angle to the catheter axis to produce images at a particular viewing angle. In other exemplary embodiments, the cMUT imaging array 110 may be arranged in an annular array with multiple rings, or a sparse or fully populated linear 1-D or 2-D array. Additionally, a plurality of combination catheter devices 100 may be formed on the same substrate and utilized in IVUS systems to provide images and sense physical and chemical information.

The substrate 105 may be made with various materials. In an exemplary embodiment of the present invention, the substrate 105 may be, but is not limited to, opaque or transparent materials such as silicon, quartz, glass, fused silica, or sapphire. Those skilled in the art will recognize that transparent materials may include any substrate that is optically transparent to a predetermined wavelength of light directed at the substrate. If the substrate 105 is silicon, the substrate 105 may be doped, and may be adapted to enable an electronic or optical signal to pass through the silicon substrate. A silicon substrate 105 may contain integrated electronics to generate and process input and output signals for the combined device. A transparent substrate 105 may be adapted to enable an optical signal to pass through the transparent substrate 105. For example, and not limitation, a silicon substrate 105 may be used as a transparent substrate 105 when using light of a predetermined wavelength as an optical signal. In some embodiments, the substrate may have a thickness in the range of approximately 10 micrometers to approximately 1 millimeter. During fabrication, the cMUT imaging array 110 and the sensors 115a-d may be coupled to the substrate.

The cMUT imaging array 110 and the sensors 115a-d may enable the combination catheter device 100 to sense images and other real-time information. For example, the cMUT imaging array 110 may be adapted to have a fluctuating capacitance and provide the fluctuating capacitance to a system that produces an image from the measured capacitance. Those skilled in the art will be familiar with various methods for translating capacitance measurements on a cMUT imaging array into an image. Additionally, the sensors 115a-d may be a variety of sensors adapted to sense a variety of real-time information. For example, and not by limitation, the sensors may be pressure sensors, temperature sensors, flow sensors, Doppler flow sensors, electrical resistivity sensors, fluid viscosity sensors, gas sensors, chemical sensors, accelerometers, or any other desirable sensor. In addition, the sensors 115a-d may be florescence or optical reflectivity sensors adapted to measure reflected and scattered light from the surrounding tissue and fluids to monitor optical parameters such as reflectivity and fluorescence. As shown, the sensors 115a-d are spaced apart from each other and placed within the cMUT imaging array 110. In other embodiments, the sensors 115a-d may be placed in other arrangements and, in some embodiments, only one sensor may be formed on the substrate 105 with the cMUT imaging array 110.

The cMUTs 110 and sensors 115a-d fabricated in accordance with the various embodiments of the present invention are fabricated from a plurality of layers. Typically, each cMUT 110 and sensor 115a-d have a bottom electrode and a top electrode, and a cavity located between the bottom electrode and top electrode. These electrodes are formed from layers of conductive material and the conductive layers may be patterned to form the electrodes. For example, and not limitation, the conductive material may be the doped silicon surface of the substrate, a doped polysilicon layer, a conductive metal or any other suitable conductive material. The electrodes may be coupled to signal generation and detection integrated circuits embedded in the silicon substrate. One challenge to using embedded integrated electronic circuitry is that the integrated electronic parts may be damaged when subjected to high temperatures. Thus, an exemplary embodiment of the present invention may enable the fabrication of a cMUT and a sensor on the same substrate above embedded integrated electronics using a low temperature fabrication technique. In another exemplary embodiment, where the silicon substrate does not contain any heat sensitive embedded electronics, low temperature fabrication methods may not be necessary. Additionally, some of the sensors formed in some embodiments of the invention may have two top electrodes rather than one bottom and top electrode.

In yet another exemplary embodiment of the present invention, the cMUTs 110 and the sensors 115a-d may be fabricated and adapted for use with transparent substrates to reflect light as a means of providing current status information. For example, and not limitation, the cMUTs 110 and sensor 115a-d electrodes may be coated with a reflective material, or may be made from a material having natural reflective properties. Fabricating a cMUT and a sensor on the same transparent substrate formed from materials such as, but not limited to, glass, quartz, or fused silica may also be possible using a low temperature fabrication process. Some other transparent substrates can be formed from materials such as sapphire and can be used to fabricate devices at elevated temperatures.

FIG. 2 is an illustration of a side view of a combination catheter device 200 having one or more cMUTs and sensors formed on a silicon substrate in accordance with an exemplary embodiment of the present invention. As shown, the device 200 includes a silicon substrate 205 having a first surface 210 and a second surface 215; cMUTs 220a-b; and sensors 225a-b. cMUTs 220a-b and sensors 225a-b may be formed on and coupled to the first surface 210 of the substrate 205. cMUTs 220a-b and sensors 225a-b may be fabricated substantially simultaneously on the first surface 210 of the substrate 205. Also shown are embedded signal generation and detection integrated circuits 240a-d. cMUT 220a is located adjacent to embedded circuit 240a, sensor 225a is located adjacent to embedded circuit 240b, sensor 220c is located adjacent to embedded circuit 240c, and cMUT 220b is located adjacent to embedded circuit 240d. In some embodiments, the circuits 240a-d may not be embedded within substrate 205 and may be coupled to cMUTs 220a-b and sensors 225a-b while on a different substrate. Additionally, the cMUTs 220a-b may be located remotely from the embedded circuits 240a-d and coupled to the embedded circuits 240a-d using various fabrication techniques.

The embedded circuits 240a-d may be adapted to electrostatically interrogate the cMUTs 220a-b and sensors 225a-b to determine current data corresponding to the current state of the cMUTs 220a-b and sensors 225a-b. For example, and not limitation, in some embodiments, embedded integrated circuits 240a, 240d may detect a capacitance value associated with cMUTs 220a-b. Similarly, the embedded integrated circuits 240b-c may sense a capacitance or resistance value associated with sensors 225a-b. Also, the embedded integrated circuits 240b-c may contain an electronic sensor, such as a temperature sensing resistor prior to the fabrication of cMUTs 220a-b and/or sensors 225a-b. The embedded integrated circuits 240a-d may contain capacitive conductive oxide semiconductor (CMOS) electronics, and may be embedded within substrate 205 prior to the formation of cMUTs 220a-b and sensors 225a-b on the first surface 210 of substrate 205. Although the substrate 205 is a silicon substrate, other embodiments of the present invention may utilize transparent substrates, or substrates composed of other materials.

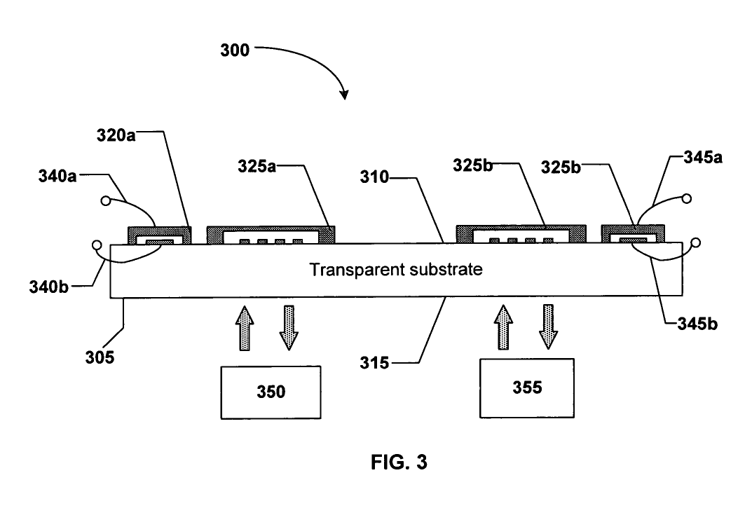

FIG. 3 is an illustration of a side view of a combination catheter device 300 having cMUTs and sensors formed on a transparent substrate in accordance with an exemplary embodiment of the present invention. As shown, the device 300 includes a transparent substrate 305 having a first surface 310 and a second surface 315. The device 300 may also include cMUTs 320a-b and sensors 325a-b formed on the first surface 310 of the substrate 305. The substrate 305 may be, but is not limited to, glass, quartz, or sapphire. In cases where silicon is substantially transparent at the wavelength of a particular light source, silicon may also be used as a transparent substrate. Thus, optical sensors 325a-b and cMUTs 320a-b with embedded electronics may be combined on the same silicon substrate. cMUTs 320a-b and sensors 325a-b may be fabricated substantially simultaneously on the first surface 310 of the transparent substrate 305. cMUTs 320a-b are also shown with electrical connections 340a-b and 345a-b. Electrical connections 340a-b may connect cMUT 320a to an optical sensor control (not shown), and electrical connections 345a-b may connect cMUT 320b to an optical sensor control (not shown). The optical sensor control may be used to adjust the optical sensor membrane position relative to the substrate to optimize the sensor sensitivity. Similarly, the optical sensor control may generate calibration and self-test signals.

Also illustrated are optical detection circuits 350, 355. Optical detection circuits 350, 355 may be adapted to optically interrogate sensors 325a-b. For example, but not limitation, optical detection circuits 350, 355 may be adapted to direct or provide a light beam to the sensors 325a-b and may be further adapted to receive a reflected light beam from the sensors 325a-b. The optical detection circuits 350, 355 may then determine the current status of the sensors 325a-b by measuring the intensity of the reflected light beam. One method of analyzing the reflected light beam may include comparing the intensity of the reflected light beam to the intensity of the light beam directed to the sensors 325, 330. The optical detection circuits 350, 355 may be fabricated on a separate substrate in some embodiments. The separate substrate may be bonded to the transparent substrate 305 so that the detection circuits 350, 355 are located adjacent to the sensors 325, 330.

One advantage associated with the use of transparent substrates is the ease of manufacturing the device. Another advantage is that optical interrogation uses light signals, not electronic signals that produce electromagnetic radiation. Thus, optical interrogation may alleviate crosstalk problems associated with electromagnetic radiation.

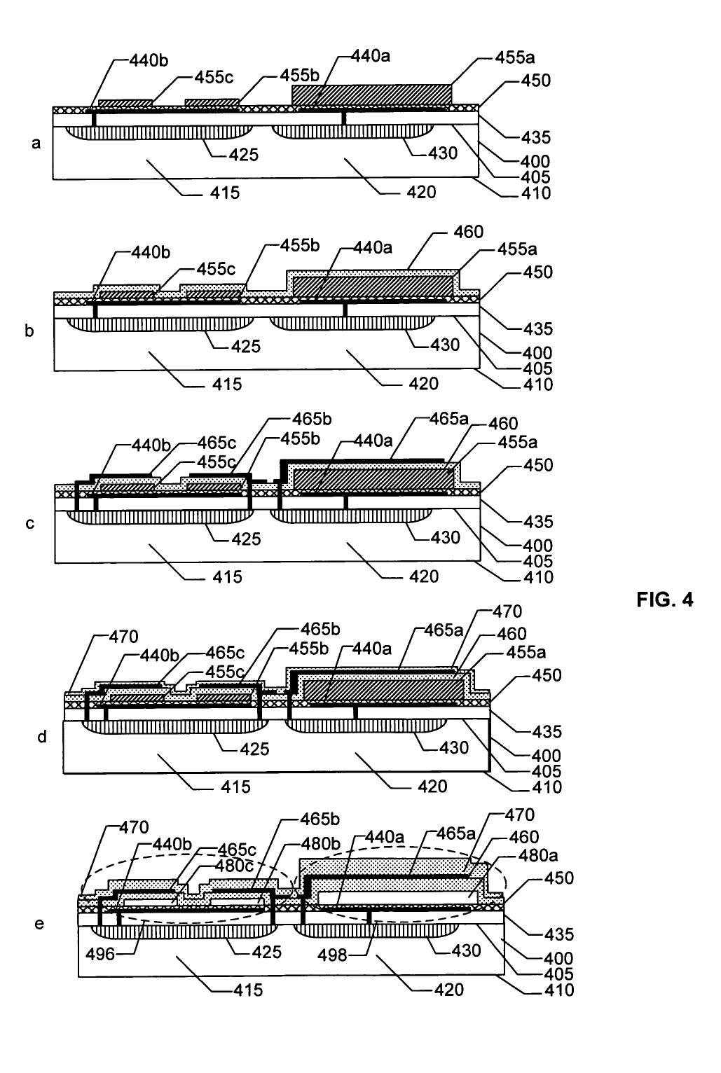

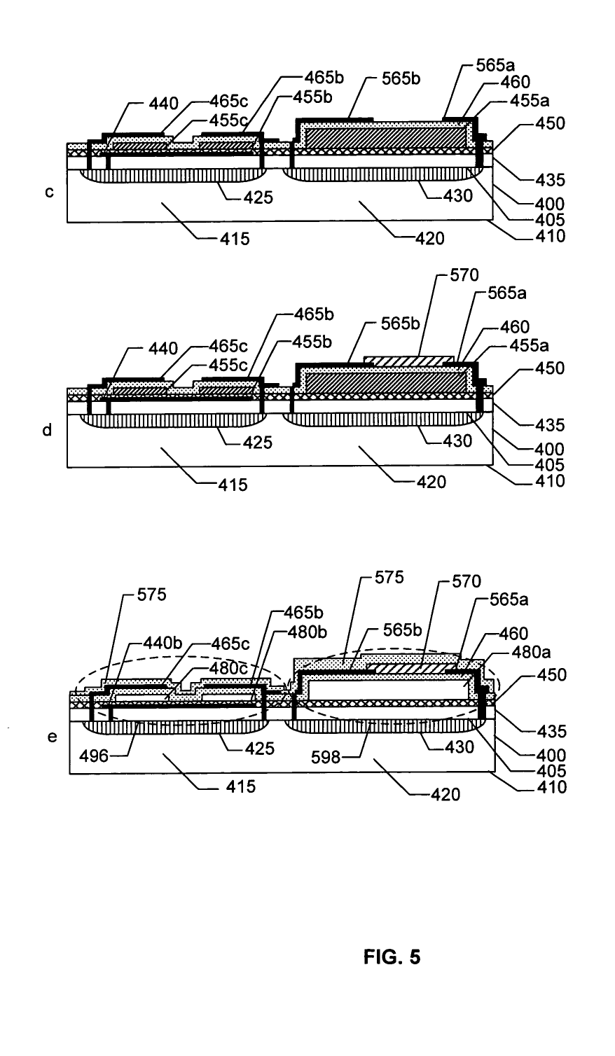

FIG. 4 is an illustration of a fabrication process utilized to produce a cMUT and a capacitive pressure sensor on a silicon substrate in accordance with an exemplary embodiment of the present invention. FIGS. 4a through 4d illustrate steps for the fabrication of a combination catheter device having a cMUT 496 and a pressure sensor 498 formed adjacent to each other on the substrate 400. Other exemplary embodiments may include a plurality of cMUTs and other sensor types fabricated in predetermined arrangements or topologies for particular applications. Typically, the fabrication process is a build-up process that involves depositing various layers of materials on a substrate and patterning the various layers in predetermined configurations to fabricate a cMUT and a sensor on the same substrate. Those skilled in the art will appreciate that other fabrication methods are available using various materials. In an exemplary embodiment of the present invention, a photoresist such as Shipley S-1813 may be used to lithographically define various layers of a combination catheter device. Such a photoresist material does not require the use of high temperature for patterning vias and material layers.

In accordance with an exemplary embodiment of the present invention, a silicon substrate 400 having a first surface 405, a second surface 410, a first embedded signal generation and detection integrated circuit 430, and a second embedded signal generation and detection integrated circuit 425 is provided as the base upon which a cMUT and a sensor may be fabricated. The substrate 400 may also include a first area portion 415 and a second area portion 420 upon which the cMUT 496 and the sensor 498 may be fabricated. Typically, the first step involves depositing an isolation layer 435 on the first surface 405 of the substrate 400. Once deposited on the first surface 405, the isolation layer 435 may be planarized and patterned in a predetermined configuration. For example, and not limitation, two via openings may be patterned into the isolation layer providing access to the first and second embedded integrated circuits 425, 430. Alternatively, the isolation layer 435 may be patterned to form other via openings or to form an isolation layer 435 having a predetermined thickness or length. FIG. 4a shows the isolation layer 435 deposited on the substrate 400 and patterned with various via openings providing access to the first and second embedded integrated circuits 425, 430. In an exemplary embodiment of the present invention, the isolation layer 435 may be silicon nitride or silicon oxide having a thickness of approximately 1 micrometer. Alternatively, the isolation layer 435 may be any suitable thickness for isolating a layer of conductive material.

In a next step, a first conductive layer 440 may be deposited on the isolation layer 435. Once deposited onto the isolation layer 435, the first conductive layer 440 may enter the via openings formed in the isolation layer 455 to contact the first surface 405 and particularly the first and second embedded detection circuits 425, 430. The first conductive layer 440 may be, but is not limited to, Aluminum, Chromium, Gold, or any other suitable conductive material. In some embodiments, the first conductive layer may be a doped silicon substrate, in which case an isolation layer may not be utilized. The first conductive layer 440 may be patterned into different parts that contact the first embedded circuit 425 and the second embedded circuit 430. For example, the first conductive layer 440 may be patterned to create a first part 440a and a second part 440b so that the first part 440a contacts the first embedded circuit 425, and the second part 440b contacts the second embedded circuit 430. The first conductive layer 440 may also be patterned to control or reduce the parasitic capacitance associated with the first conductive layer 440. For example, the first conductive layer 440 may be patterned so that the first part 440a and second part 440b overlie or correspond to the first and second embedded integrated circuits 425, 430. FIG. 4a shows the conductive layer 440 patterned into two parts 440a-b, each overlying and contacting one of the first and second embedded integrated circuits 425, 430.

Once the first conductive layer 440 is patterned into a predetermined configuration, a second isolation layer 450 may be deposited on the first conductive layer 440. The second isolation layer 450 protects the first conductive layer 440 and the silicon substrate 400 from ethcants used in fabricating the cMUT 496 and the sensor 498 on the same substrate. The second isolation layer 450 may be a layer of silicon nitride, and may be approximately 1500 Angstroms thick. For example, and not limitation, a Unaxis 790 plasma enhanced chemical vapor deposition (PECVD) system may be used to deposit the second isolation layer 450 at approximately 250 degrees Celsius. Some embodiments of the present invention may not include the second isolation layer 450. FIG. 4a shows the second isolation layer 450 deposited over the first and second conductive parts 440a-b.

In a next step, a sacrificial layer 455 may be deposited on the first conductive layer 440. The sacrificial layer 455 is only a temporary layer and is preferably etched away in an exemplary embodiment of the present invention. The sacrificial layer 455 is used to hold a space while additional layers are deposited on the sacrificial layer 455. Such a sacrificial layer 455 may be used to create a hollow chamber or create a space for a via opening. The sacrificial layer 455 may be formed out of amorphous silicon which may be deposited using a Unaxis 790 PECVD system at approximately 300 degrees Celsius. Once deposited, the sacrificial layer 455 may be patterned into a plurality of portions. For example as illustrated in FIG. 4a, the sacrificial layer 455 may be patterned into a first portion 455a, a second portion 455b, and a third portion 455c using dry plasma etching. Further, the plurality of portions 455a-c may be patterned so that portions 455b-c overlie or correspond to the first embedded integrated circuit 425 and portion 455a overlies or corresponds to the second embedded integrated circuit 430. The plurality of portions 455a-c may also be selectively deposited, planed, or patterned to predetermined thicknesses. For example as depicted in FIG. 4a, portion 455a is thicker than portions 455b-c. Patterning the portions 455a-c into different thicknesses may be accomplished by etching to the predetermined thickness, depositing enough material to achieve the predetermined thickness, or a combination of both. The sacrificial layers may be patterned and their thickness may be adjusted using reactive ion etching (RIE) methods. In an exemplary embodiment of the present invention, portions of the sacrificial layer correspond to cavities that will be formed adjacent a membrane in a cMUT or a sensor.

Once the sacrificial layer 455 is patterned appropriately, a first membrane layer 460 is deposited onto the portions 455a-c of the sacrificial layer 455. The first membrane layer 460 is deposited onto the portions 455a-c of the sacrificial layer 450 to cover the portions 455a-c as shown in FIG. 4b. For example, and not limitation, the first membrane layer 460 may be deposited using a Unaxis 790 PECVD system. The first membrane layer 460 may be a layer of silicon nitride and may be patterned to have a thickness of approximately 6000 Angstroms. Alternatively, the thickness of the first membrane layer 460 may have any predetermined thickness or depend on the particular implementation. After patterning the first membrane layer 460, a second conductive layer 465 may be deposited onto the first membrane layer 460.

In an exemplary embodiment of the present invention, the second conductive layer 465 may form the top electrode for the cMUT 496 and the sensor 498 formed on the substrate 400. The second conductive layer 465 may be, but is not limited to, Aluminum, Chromium, Gold, or any other suitable conductive material such as doped polysilicon. Additionally, the second conductive layer 465 may be the same conductive material or may be a different conductive material than the first conductive layer 440. Similar to the first conductive layer 440, the second conductive layer 465 may be patterned into a plurality of parts. For example, and not limitation, as shown FIG. 4c, the second conductive layer 465 is patterned and divided into a first part 465a, a second part 465b, and third part 465c. The first part 465a overlies the third portion 455a of the sacrificial layer 455 and the second embedded detection circuit 430; the second part 465b overlies the second portion 455b of the sacrificial layer 455 and the first embedded detection circuit 425; and the third part 465c overlies the third portion 455c of the sacrificial layer 455 and the first embedded detection circuit 425.

The second conductive layer 465 may also be deposited into via openings formed in the first membrane layer 460, second isolation layer 450, and first isolation layer 435, so that the second conductive layer 465 is coupled to the first embedded integrated circuit 425 and the second embedded integrated circuit 430. Specifically, the via openings may enable the first part 465a of the second conductive layer 465 to contact the second embedded integrated circuit 430, and the second part 465b of the second conductive layer 465 and the third part 465c to contact the first embedded integrated circuit 425 as shown in FIG. 4c. The various via openings enabling the second conductive layer 465 to access the first and second embedded integrated circuits 425, 430 and the first surface 405 of the substrate 400 may be formed in the first membrane layer 460, the second isolation layer 450, and the first isolation layer 435. These via openings may be patterned or etched into the first membrane layer 460, the second isolation layer 450, and the first isolation layer 435 using various patterning techniques known to those skilled in the art after deposition of these layers.

In a next step, a second membrane layer 470 is deposited over the parts 465a-c of the second conductive layer 465. The second membrane layer 470 covers the parts 465a-c of the second conductive layer 465 as shown in FIG. 4d. The second membrane layer 470 may be a layer of silicon nitride, or other suitable material, and may be patterned to have a thickness of approximately 6000 Angstroms. Alternatively, the thickness of second membrane layer 470 may be any other desired thickness. In some embodiments, the second membrane layer 470 may be adjusted using deposition and patterning techniques so that the second membrane layer has an optimized geometrical configuration as shown in FIG. 4e. Once the second membrane layer 470 is adjusted according to a predetermined geometric configuration, the sacrificial layer portions 455a-c may be etched away, thereby forming a plurality of cavities 480a-c.

The cavities 480a-c may be formed between the pieces 440a-b of the first conductive layer 440 and the parts 465a-c of the second conductive layer 465. More specifically, a first cavity 480a may be formed between the first piece 440a of the first conductive layer 440 and the first part 465a of the second conductive layer 465, a second cavity 480b may be formed between the second piece 440b of the first conductive layer 440 and the second part 465b of the second conductive layer 465, and a third cavity 480c may be formed between the second piece 440b of the first conductive layer 440 and the third part 465c of the second conductive layer 465. The cavities 480a-c may also be disposed between or defined by the second isolation layer 450 and the first membrane layer 460. The cavities 480a-c may be formed to have a predetermined height in accordance with an exemplary embodiment of the present invention. After the cavities 480a-c are formed by etching the portions 455a-c of the sacrificial layer 455, the cavities 480a-c may be vacuum sealed by depositing a sealing layer (not shown) on the second membrane layer 470. The sealing layer may be a layer of silicon nitride, and may have a thickness greater than the height of the cavities 480a-c. In an exemplary embodiment, the sealing layer may have a thickness of approximately 4500 Angstroms and the height of cavities 480a-c may be approximately 1500 Angstroms. In alternative embodiments, the second membrane layer may be sealed using a local sealing technique or sealed under predetermined pressurized conditions.

After the second membrane layer 470 is sealed and optimized geometrically, the end result is a cMUT 496 and a sensor 498 formed on the substrate 400. As shown in FIG. 4e, the cMUT 496 has one bottom electrode 440b and two top electrodes 465b, 465c, and is located adjacent to and coupled to the first embedded integrated circuit 425. Also, the sensor 498 has one bottom electrode 440a and one top electrode 465a, and is located adjacent to and coupled to the second embedded integrated circuit 430. Due to the elastic characteristics of the first and second membrane layers 460, 470, the top electrodes 465a-c may move relative to the bottom electrodes 440a-b. When an external mechanical disturbance is applied to the top electrodes 465a-c and the bottom electrodes 440a-b, which may be kept at different electrical potentials or have electrical charges on them, movement of the top electrodes 465a-c may cause a change in the capacitance value of the cMUT 496 and the sensor 498. The first embedded integrated circuit 425 detects the change in capacitance associated with the cMUT 496, and the second embedded integrated circuit 430 detects the change in capacitance associated with sensor 498. The sensor 498 illustrated in FIG. 4e is a capacitive pressure sensor, but those skilled in the art will understand that other types of sensors may be fabricated on the substrate without departing from the spirit and scope of the present invention.

FIG. 5 is an illustration of a fabrication process utilized to produce a cMUT and a piezoresistive pressure sensor on a silicon substrate in accordance with an exemplary embodiment of the present invention. FIG. 5 illustrates intermediate steps c-e used to form a cMUT 496 and piezoresistive pressure sensor 598 on the same substrate 400. Steps a-b of FIG. 5 are the same as steps a-b illustrated in FIG. 4a-b, and are not discussed at length again. Additionally, the steps of forming cMUT 496 are also the same as those illustrated in FIG. 4a-e, so the discussion of FIG. 5 focuses on the fabrication of the piezoresistive pressure sensor 598. To fabricate the piezoresistive pressure sensor 598, a first isolation layer 435, a second isolation layer 450, a sacrificial layer 455, and a first membrane layer 460 may be deposited and patterned onto a substrate 400. As illustrated in FIG. 5c the sacrificial layer 455 is then patterned into a plurality of portions and portion 455a corresponds to the piezoresistive pressure sensor 598.

After portion 455a of the sacrificial layer 455 has been patterned according to a predetermined configuration, the second conductive layer 465 is deposited onto portion 455a to cover portion 455a. In addition, the second conductive layer 465 may be deposited into two via openings formed in the first isolation layer 435, the second isolation layer 450, and the first membrane layer 460. Depositing the second conductive layer 465 in these via openings enables the second conductive layer 465 to contact the second embedded detection circuit 430 as illustrated in FIG. 5c. In an exemplary embodiment of the present invention, the via openings provide access to the second embedded detection circuit 430, and are formed in each layer as deposited. Next, the second conductive layer 465 may be patterned into parts 565a-b. Parts 565a-b form the two electrodes for the piezoresistive pressure sensor 598. After the second conductive layer 465 is patterned to form the second conductive layer parts 565a-b, a resistive layer 570 may be deposited and patterned onto the first membrane layer 460 between the second conductive layer parts 565a-b as shown in FIG. 5d. In an exemplary embodiment, the resistive material is polysilicon. Alternatively, the resistive material may be any resistive material and may have a substantial piezoresistive coefficient. Once the resistive layer 570 is patterned according to a predetermined configuration, a second membrane layer 575 may be deposited onto the resistive layer to form the piezoresistive pressure sensor 598.

Next, the sacrificial portion 455a may be etched forming a cavity 480a. The second conductive layer parts 565a-b overlie cavity 480a, and the first membrane layer 460 defines the cavity 480a located above the substrate 400. After the cavity 480a has been formed by the etching of the sacrificial portion 455a, the second membrane layer 575 may be sealed to complete the fabrication of cMUT 496 and the piezoresistive pressure sensor 598. The piezoresistive pressure sensor 598 may be located adjacent to and coupled to the second embedded integrated circuit 430. Alternatively, the piezoresistive pressure sensor 598 may be located remotely from, but coupled to the second embedded integrated circuit 430. In operation, the piezoresistive pressure sensor 598 may change resistive values corresponding to the mechanical characteristics of the first and second membrane layers 460, 575 in response to a pressure change in the medium in which the combination device is inserted, thus forming a part of piezoresistive pressure sensor 598. The change of resistive value may be detected by the second embedded integrated circuit 430 since the second conductive layer parts 565a-b are coupled to the second embedded integrated circuit 430.

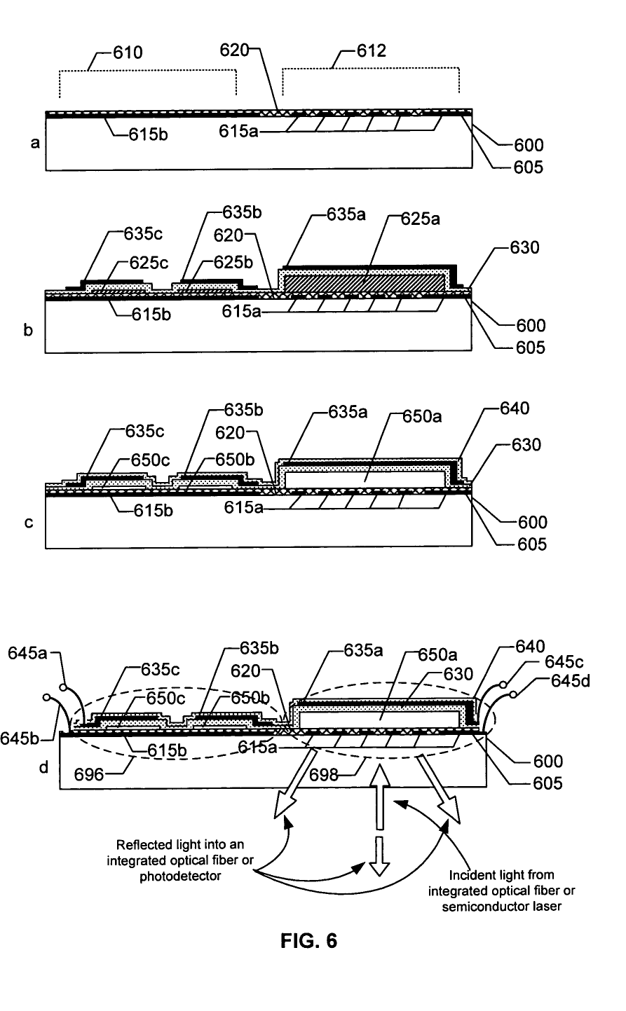

FIG. 6 is an illustration of a fabrication process utilized to produce a cMUT and a pressure sensor on a transparent substrate in accordance with an exemplary embodiment of the present invention. As shown in FIG. 6, a cMUT 696 and a sensor 698 may be fabricated on a transparent substrate 600. The transparent substrate 600 has a first surface 605, a first surface area portion 610, and a second surface area portion 612. The surface area portions 610 and 612 may be located on, and any area on or within surface 605, and are generally designated by dashed areas 610, 612. FIGS. 6a through 6d illustrate intermediate states of the formation of a combination catheter device having a cMUT 696 and a sensor 698 formed adjacent to each other on the transparent substrate 600. The cMUT 696 may be formed within the first surface area 610 while the sensor 698 may be formed within the second surface area 612.

Typically, the first step of fabricating the cMUT 696 and the sensor 698 on the transparent substrate 600 involves depositing a first conductive layer 615 onto the first surface 605 of the substrate 600. After depositing the first conductive layer 615 onto the substrate 600 the first conductive layer 615 may be patterned into two pieces 615a-b. For example, a portion of the first conductive layer 615 deposited over the second surface area 612 may be patterned into a diffraction grating 615a comprising a plurality of optical grated electrodes as depicted in FIG. 6a. The first conductive layer 615 may be Aluminum, any other conductive material, may have a substantial reflectivity at a desired optical wavelength, and may be approximately 0.2 micrometers thick or any other desired thickness. In addition, an adhesive may be used in some embodiments between the first conductive layer 615 and the transparent substrate 600 to ensure good adhesion between the first conductive layer 615 and the transparent substrate 600.

After the first conductive layer 615 is planed and patterned to a predetermined thickness and pattern, an isolation layer 620 may be deposited onto the first conductive layer 615 as shown in FIG. 6a. The isolation layer 620 may be silicon nitride and may have a thickness of approximately 1500 Angstroms. After depositing the isolation layer 620, it may be planed and patterned to a predetermined thickness and configuration. In a next step, a sacrificial layer 625 may be deposited onto the isolation layer 620 and patterned into a plurality of portions 625a-c. For example as illustrated in FIG. 6b, the sacrificial layer 625 may be divided into a first portion 625a overlying the second surface area 612, and a second portion 625b and a third portion 625c, both overlying the first surface area 610. The portions 625a-c of the sacrificial layer 625 may have varying thicknesses accomplished by a combination of selective deposition techniques or selective patterning techniques. For example, the first portion 625a has a greater thickness than portions 625b-c as illustrated in FIG. 6b. After patterning the sacrificial layer 625, a first membrane layer 630 is deposited onto the portion 625a-c of the sacrificial layer 625.

The first membrane layer 630 is deposited onto the portions 625a-c of the sacrificial layer 625 to cover the portions 625a-c as shown in FIG. 6c. The first membrane layer 630 may be a layer of silicon nitride and may be patterned to have a thickness of approximately 6000 Angstroms. Next, a second conductive layer 635 may be deposited onto the first membrane layer 630.

The second conductive layer 635 may form the top electrode for the cMUT 696 and the sensor 698 formed on the transparent substrate 600. The second conductive layer 635 may be Aluminum, Chromium, Gold, or any suitable conductive material, and may be different or the same as the first conductive layer 615. Similar to the first conductive layer 615, the second conductive layer 635 is patterned into a plurality of parts. For example, as shown FIG. 6b, the second conductive layer 635 is patterned and divided into a first part 635a, a second part 635b, and a third part 635c. The first part 635a overlies the first portion 625a of the sacrificial layer 625 and the second surface area 612, the second part 635b overlies the second portion 625b of the sacrificial layer 625 and the first surface area 610, and the third part 635c overlies the third portion 625c of the sacrificial layer 635 and the first surface area 610.

In a next step, a second membrane layer 640 is deposited over the parts 635a-c of the second conductive layer 635. The second membrane layer 640 covers the parts 635a-c of the second conductive layer 635 as shown in FIG. 6c. The second membrane layer 640 may be a layer of silicon nitride and may be patterned to have a thickness of approximately 6000 Angstroms. In some embodiments, the second membrane layer 640 may be adjusted using selective deposition and patterning techniques so that the second membrane layer 640 has an optimized geometrical configuration. Once the second membrane layer 640 is adjusted according to a predetermined geometric configuration, the sacrificial layer portions 625a-c are etched forming a plurality of cavities 650a-c.

The cavities 650a-c may be formed between the pieces 615a-b of the first conductive layer 615 and the pieces 635a-c of the second conductive layer 635. For example as illustrated in FIG. 6c, a first cavity 650a may be formed between the diffraction grating 615a of the first conductive layer 615 and the first part 635a of the second conductive layer 635, a second cavity 650b may be formed between the second piece 615b of the first conductive layer 615 and the second part 635b of the second conductive layer 635, and a third cavity 650c may be formed between the second piece 615b of the first conductive layer 615 and the third part 635c of the second conductive layer 635. The cavities 650a-c may also be disposed between and defined by the isolation layer 620 and the first membrane layer 630. The cavities 650a-c may be formed to have predetermined heights in accordance with an exemplary embodiment of the present invention.

After the cavities 650a-c are formed by etching the portions 625a-c of the sacrificial layer 625, the cavities 650a-c may be vacuum sealed by depositing a sealing layer (not shown) on the second membrane layer 640. The sealing layer may be a layer of silicon nitride, and may have a thickness greater than the height of the cavities. In an exemplary embodiment, the sealing layer may have a thickness of approximately 4500 Angstroms and the height of cavities 650a-c may be approximately 1500 Angstroms. In alternative embodiments, the second membrane layer 640 may be sealed using a local sealing technique or sealed at a predetermined pressure.

After the second membrane layer 640 is sealed and optimized geometrically, the end result is a cMUT 696 and a sensor 698 formed on the same transparent substrate 600. As shown in FIG. 6d, the cMUT 696 has one bottom electrode 615b and two top electrodes 635b, 635c, and is located in the first surface area 610 of the substrate 600. Also, the sensor 698 has a plurality of bottom electrodes spaced apart from each other forming a diffraction grating 615a, one top electrode 635a, and is located in the second surface area 612 of the substrate 600. The top electrode 635a may be adapted to reflect a light beam, or may be made with a conductive material having reflective properties. Due to the elastic characteristics of the first membrane layer 630 and second membrane layers 640, the top electrodes 635a-c move relative to the bottom electrodes 615a-b.

Electrical connections may also be connected to the cMUT 698 and the sensor 698. As shown in FIG. 6d, electrical connections 645a-b may be connected to the electrodes 615b, 635c of cMUT 698 through via openings formed in the isolation layer 620, the first membrane layer 630, and the second membrane layer 640. In addition, electrical connections 645c-d may be connected to the electrodes 615a, 635a of the sensor 698 through via openings formed in the isolation layer 620, the first membrane layer 630, and the second membrane layer 640. The via openings formed in the isolation layer 620, the first membrane layer 630, and the second membrane layer 640 are preferably formed during the patterning of each layer, but those skilled in the art will recognize that other processes may be used to form these via openings.

In operation, a light beam may be directed through the transparent substrate 600 and the diffraction grating 615b to electrode 635a of the sensor 600. The diffraction grating 615b and the electrode 635a may be made with a reflective material or otherwise adapted to reflect light so that the diffraction grating 615b electrode 635a will reflect the light beam directed at it as illustrated by the arrows in FIG. 6d. Due to the elastic characteristics of the first and second membrane layers 630, 640 the electrode 635a may move relative to the diffraction grating 615b in response to external pressure applied to sensor 698. When electrode 635a moves, it will cause the intensity of the any reflected light to adjust. In an exemplary embodiment of the present invention the adjusted intensity may be compared with the intensity of the directed light beam to determine pressure being applied to the sensor 698.

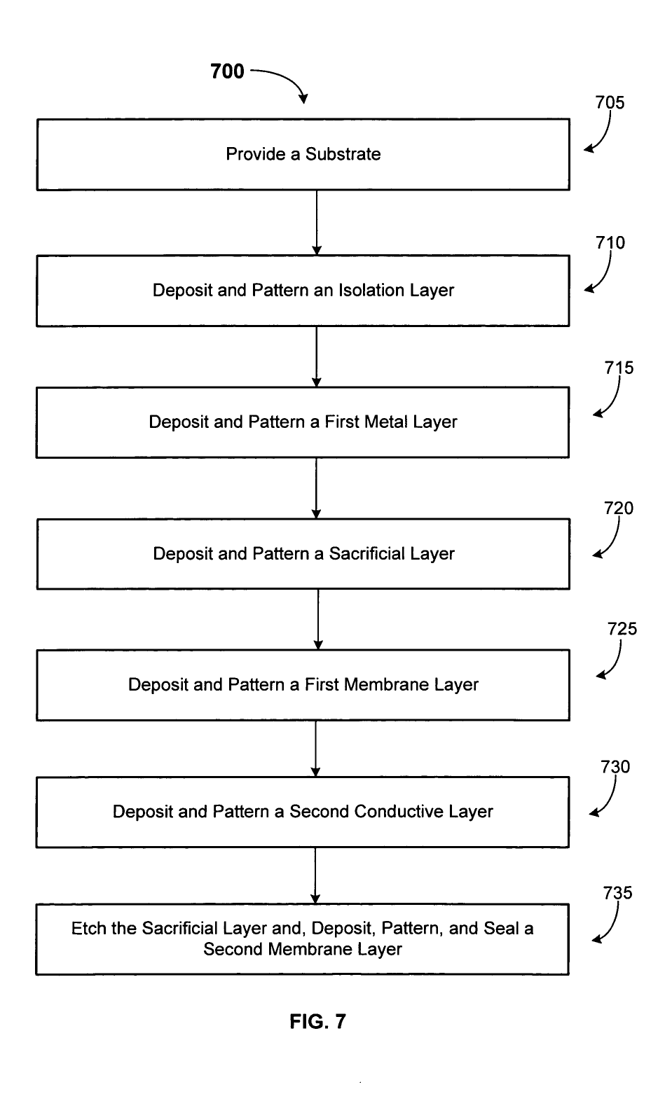

FIG. 7 is a logic flow diagram depicting a method of fabricating a combination catheter device in accordance with an exemplary embodiment of the present invention. Typically, the first step involves providing a substrate (step 705). In an exemplary embodiment of the present invention, the provided substrate may be an opaque or transparent substrate. Next, an isolation layer may be deposited onto the substrate and patterned to have a predetermined thickness (step 710). After the isolation layer is patterned, a first conductive layer may be deposited onto the isolation layer and patterned into a plurality of pieces (step 715). The first conductive layer forms the bottom electrodes for the cMUT and the sensor formed on the same substrate. Once the first conductive layer is patterned into a predetermined configuration, a sacrificial layer may be deposited onto the pieces of the first conductive layer (step 720). The sacrificial layer is then patterned into a plurality of sacrificial portions and may be further patterned by selective deposition and patterning techniques so that the plurality of portions have varying thicknesses. Then, a first membrane layer is deposited onto the sacrificial layer (step 725).

The deposited first membrane layer is then patterned to have a predetermined thickness, and then a second conductive layer is deposited onto the first membrane layer (step 730). The second conductive layer is then patterned into various parts. The various parts of the second conductive layer form the top electrodes for the cMUT and the sensor. After the second conductive layer is patterned into a predetermined configuration, a second membrane layer is deposited onto the patterned second conductive layer (step 735). The second membrane layer may also be patterned to have a predetermined optimized geometric configuration. The first and second membrane layers encapsulate the various parts of the second conductive layer and enable these parts to move relative to the pieces of the first conductive layer due to the elastic characteristics of the first and second membrane layers. After the second membrane layer is patterned, the sacrificial layers are etched forming cavities between the first and second conductive layers (step 735). The cavities are formed below the first and second membrane layers and the cavities provide space for the resonating first and second membrane layers to move relative to the substrate. In a last step, the second membrane layer may be sealed by depositing a sealing layer onto the second membrane layer.

While the various embodiments of this invention have been described in detail to particular reference to exemplary embodiments, those skilled in the art will understand that variations and modifications may be effected within the scope of the invention as defined in the appended claims.

1. A combination catheter device comprising:
a substrate having a first surface;
a first capacitive micromachined ultrasonic transducer (cMUT) coupled to the first surface of the substrate; and
a first sensor coupled to the first surface of the substrate.

2. The device of claim 1, wherein the first sensor is a pressure sensor.

3. The device of claim 1, wherein the first sensor is a flow sensor.

4. The device of clam 1, wherein the first sensor is a chemical sensor.

5. The device of claim 1, wherein the first sensor is adapted to reflect light.

6. The device of claim 1, wherein the substrate further comprises a first embedded integrated circuit coupled to the first cMUT.

7. The device of claim 6, wherein the substrate further comprises a second embedded integrated circuit coupled to the sensor.

8. The device of claim 1, wherein the substrate is a silicon substrate adapted to enable an electrical signal to pass through said silicon substrate.

9. The device of claim 1, wherein the substrate is a transparent substrate adapted to enable a signal to pass through the transparent substrate.

10. The device of claim 9, wherein the transparent substrate comprises sapphire.

11-28. (canceled)

29. A method of fabricating a combination catheter comprising:
providing a substrate comprising a surface;
forming a cMUT on the surface of the substrate; and
forming a sensor on the surface of the substrate.

30. The method of claim 29 further comprising substantially simultaneously forming the cMUT and the sensor on the surface of the substrate.

31. The method of claim 29, wherein the step of providing a substrate comprises providing a silicon substrate.

32. The method of claim 31 further comprising coupling the cMUT to a first integrated circuit and coupling the sensor to a second integrated circuit, wherein the first and second integrated circuits are embedded in the silicon substrate.

33. The method of claim 31, wherein the steps of forming the cMUT and the sensor further comprise:
providing a first conductive layer on the surface of the silicon substrate;
depositing and patterning a sacrificial layer on at least a portion of the first conductive layer;
depositing and patterning a first membrane layer on the sacrificial layer;
depositing and patterning a second conductive layer on at least a portion of the first membrane layer;
depositing and patterning a second membrane layer on at least a portion of the second conductive layer; and
etching the sacrificial layer.

34. The method of claim 33 comprising disposing a first isolation layer between the surface of the substrate and the first conductive layer.

35. The method of claim 33 further comprising adjusting at least a portion of the second membrane layer to have a predetermined geometric configuration.

36. The method of claim 33 further comprising depositing and patterning a second isolation layer over at least a portion of the first conductive layer.

37. The method of claim 33 further comprising depositing and patterning a piezoresistive layer coupled to at least a portion of the first membrane layer.

38. The method of claim 33, wherein the step of providing a first conductive layer on the surface of the silicon substrate comprises doping the silicon substrate.

39-60. (canceled)
